(19) United States
(12) Patent Application Publication
(10) Pub. No.: US 2025/0075942 A1
(43) Pub. Date: Mar. 6, 2025

(54) WATER HEATING DEVICE

(71) Applicant: Viessmann Climate Solutions SE, Allendorf (DE)

(72) Inventor: Gerold SCHULZE, Kassel (DE)

(73) Assignee: Viessmann Climate Solutions SE, Allendorf (DE)

(21) Appl. No.: 18/711,926

(22) PCT Filed: Feb. 7, 2023
(86) PCT No.: PCT/DE2023/150005

§ 371 Date: May 21, 2024

(30) Foreign Application Priority Data
Feb. 16, 2022 (DE) 10 2022 103 569.7

(51) Int. Cl. F24H 9/1818; F24H 15/37

(52) U.S. Cl. CPC F24H 9/1818; F24H 15/37

(57) ABSTRACT

A water heating device includes a space that is filled with water, an electric heating device provided for heating the water in the space and power electronics arranged at the space and provided for controlling the heating device. An electrothermal converter is provided for controlled transfer of heat between the power electronics and a wall of the space which is in contact with the water.

The invention relates to a water heating device according to the preamble of patent claim 1.

A water heating device of the type mentioned at the beginning is known from the patent document DE 20 2004 012 263 U1. This water heating device, which is designed as an instantaneous water heater, consists of a space that is filled with water, an electric heating device, which is provided for heating the water in the space, and power electronics, which are arranged at the space and are provided for controlling the heating device. In this case, the said space is designed in the said solution as a water-bearing pipe. For cooling the power electronics, it is provided that the triac thereof can output the waste heat produced to the water in the space. In this case, the temperature gradient that is present determines the heat transfer that actually takes place.

The invention is based on the object of improving a water heating device of the type mentioned at the beginning. In particular, a water heating device is created, having cooling of the power electronics, which is to be controlled precisely.

This object is achieved using a water heating device of the type mentioned at the beginning, by means of the features listed in the characterizing part of patent claim 1.

According to the invention, it is therefore provided that for controlled transfer of heat between the power electronics and a wall of the space, which is in contact with the water, an electrothermal converter, particularly a Peltier element, is provided.

In other words, the water heating device according to the invention is therefore distinguished in that with the aid of the electrothermal converter, it is possible to determine in a targeted manner how much heat should be output by the power electronics to the water. Or in other words: the cooling of the power electronics can be controlled very accurately according to the invention.

Here, it is to be noted that the term “control” used in this application is used for simplicity in the sense of the English term “control”, i.e. it corresponds either, specifically preferably, to a control with feedback or alternatively a control without feedback. In other words, the last-mentioned option in Patent claim 1 could also be written as follows: “for feedback-free control of the heating device” or “for transfer of heat which is controlled in a feedback-free manner”.

Other advantageous developments can be drawn from the dependent patent claims.

The water heating device according to the invention, including the advantageous developments thereof according to the dependent patent claims is explained in more detail below with reference to the illustration of a preferred exemplary embodiment in the drawing.

### IN THE FIGURE

FIG. 1 schematically shows the water heating device according to the invention.

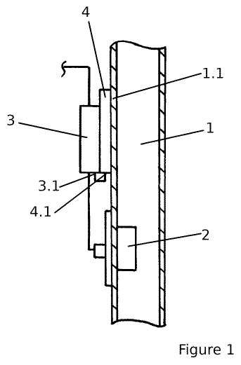

The water heating device, which is illustrated in the single figure, first consists in a known manner of a space 1 that is filled with water, an electric heating device 2, which is provided for heating the water in the space 1, and power electronics 3, which are arranged at the space 1 and are provided for controlling the heating device 2.

The said space 1 is in this case preferably optionally designed as a hot water storage tank of a heating system or as a throughflow space (particularly pipe) of an electric instantaneous water heater.

It is important for the water heating device according to the invention that for controlled transfer of heat between the power electronics 3 and a wall 1.1 of the space 1, which is in contact with the water and preferably metallically constructed, an electrothermal converter 4 is provided. In terms of the method, it is provided in this case that heat generated at the power electronics 3 is transferred with the aid of the electrothermal converter 4 to the water located in the space 1. Due to this measure, in the end it is even possible due to the targeted use of the waste heat to design the power electronics 3 smaller than previously.

Considered in more detail, it is particularly preferably provided in this case that for adjusting the transfer of heat (that is to say the actual amount of heat in particular), a current flowing through the electrothermal converter 4 is designed to be controllable, preferably by means of a superordinate control device of the water heating device.

To this end, it is further preferably provided that a power supply connection 4.1 of the electrothermal converter 4 is designed to be electrically connected to a power outlet connection 3.1 of the power electronics 3. Or once more expressed somewhat differently: The power electronics 3 and the electrothermal converter 4 are preferably electrically connected to one another and the same current flows through them.

In particular for the case that the water heating device is arranged in a comparatively warm environment, it is further preferably provided that the electrothermal converter 4 is designed for absorbing heat from the air moving around the electrothermal converter 4.

In order to be able to heat the water in the space 1 particularly efficiently, it is further preferably provided that the electric heating device 2 is designed as a resistance heater arranged in the space 1, particularly as a heating element.

Furthermore, it is preferably provided that the power electronics 3 optionally have at least one thyristor, one metal oxide semiconductor field effect transistor, one bipolar transistor and/or a different semiconductor.

Finally (in a closer examination), it is very particularly preferably provided that the electrothermal converter 4 is designed as a Peltier element (in relation to this, see also https://de.wikipedia.org/w/index.php?title=PeltierElement &oldid=213265538).

### REFERENCE LIST

1 Space
1.1 Wall
2 Heating device
3 Power electronics
3.1 Power output connection
4 Electrothermal converter
4.1 Power supply connection

1. A water heating device comprising a space (1) that is filled with water, an electric heating device (2), which is provided for heating the water in the space (1), and power electronics (3), which are arranged at the space (1) and are provided for controlling the heating device (2),
wherein for controlled transfer of heat between the power electronics (3) and a wall (1.1) of the space (1), which is in contact with the water, an electrothermal converter (4) is provided.

2. The water heating device according to claim 1,
wherein for adjusting the transfer of heat, a current flowing through the electrothermal converter (4) is designed to be controllable.

3. The water heating device according to claim 1,
wherein a power supply connection (4.1) of the electrothermal converter (4) is designed to be electrically connected to a power outlet connection (3.1) of the power electronics (3).

4. The water heating device according to claim 1,
wherein the electrothermal converter (4) is designed for absorbing heat from air moving around the electrothermal converter (4).

5. The water heating device according to claim 1
in that wherein the space (1) is optionally designed as a hot water storage tank of a heating system or as a throughflow space of an electric instantaneous water heater.

6. The water heating device according to claim 1,
wherein the electric heating device (2) is designed as a resistance heater arranged in the space (1).

7. The water heating device according to claim 1,
in that wherein the power electronics (3) optionally have at least one thyristor, one metal oxide semiconductor field effect transistor, one bipolar transistor and/or a different semiconductor.

8. The water heating device according to claim 1,
wherein the electrothermal converter (4) is designed as a Peltier element.

9. The water heating device according to claim 1,
wherein the wall (1.1) is metallically constructed.

10. A method for operating a water heating device according to claim 1,
wherein heat generated at the power electronics (3) is transferred with the aid of the electrothermal converter (4) to the water located in the space (1).
